(19) United States
(12) Patent Application Publication
(10) Pub. No.: US 2024/0125464 A1
(43) Pub. Date: Apr. 18, 2024

(54) Heat Dissipation Arrangement for LED Lighting Fixtures

(71) Applicant: Anders Grau SUNDSTRÖM, Näsåker (SE)

(72) Inventor: Anders Grau SUNDSTRÖM, Näsåker (SE)

(21) Appl. No.: 18/533,331

(22) Filed: Dec. 8, 2023

(30) Foreign Application Priority Data
Dec. 9, 2002 (SE) 2230404-2

(51) Int. Cl. F21V 29/76; F21V 29/87; F21V 29/89

(52) U.S. Cl. CPC F21V 29/76; F21V 29/87; F21V 29/89; F21Y 2115/10

(57) ABSTRACT

An LED lighting fixture has a plurality of LEDs mounted on a board, together forming an LED module. A covering is provided on the LED module on an opposite side of the board relative to the LEDs. The covering has at least one fin extending substantially perpendicular to the LED module. Each fin has an internal channel in which a heat-conducting element is provided. The heat-conducting element has a greater thermal conductivity than the fin and is substantially encapsulated by the fin.

### REFERENCE TO RELATED APPLICATIONS

This application is a continuation-in-part of and claims priority of Swedish Patent Application No. 2230404-2, filed 9 Dec. 2022.

### TECHNICAL FIELD

This invention relates to LED lighting fixtures.

### BACKGROUND OF THE INVENTION

Most LED fixtures on the market today are manufactured from aluminum since it is a well-tested material and has good thermal conductivity and can conduct heat very well. If LED diodes are driven at high temperatures that exceed the recommended operating temperatures, they can be damaged and their service life can be shortened. Aluminum, however, has its disadvantages in that it can oxidize, for example, as a result of the fixture being damaged during handling; to scratch or damage the treated surface could lead to the metal being exposed, with the risk of oxidation. Aluminum is sensitive to outdoor and salty environments in any case even if it is protected with the proper treatment. Aluminum fixtures can also weigh quite a lot depending on their construction.

### BRIEF DESCRIPTION OF THE DRAWINGS

FIG. 1 is a perspective view from above of one embodiment of a heat sink arrangement for an LED lighting fixture.

FIG. 2 shows a cross-sectional view of the embodiment of the heat sink arrangement taken in direction B-B indicated in FIG. 1.

FIGS. 3 and 4 show a side view of the embodiment of the heat sink arrangement, where FIG. 3 is a cross-sectional view in the direction A-A as shown in FIG. 4.

FIG. 5 depicts an underside of an embodiment of the heat sink arrangement, that is, the side on which LED elements are mounted and can shine.

### DETAILED DESCRIPTION

At the highest level, different embodiments of the invention provide a heat sink arrangement for LED lighting fixtures in which relatively highly heat-conductive elements are located and substantially encapsulated within interior spaces of fins of a relatively lower heat-conductive armature that covers the heat-producing members of the lighting fixture, including the LED devices themselves.

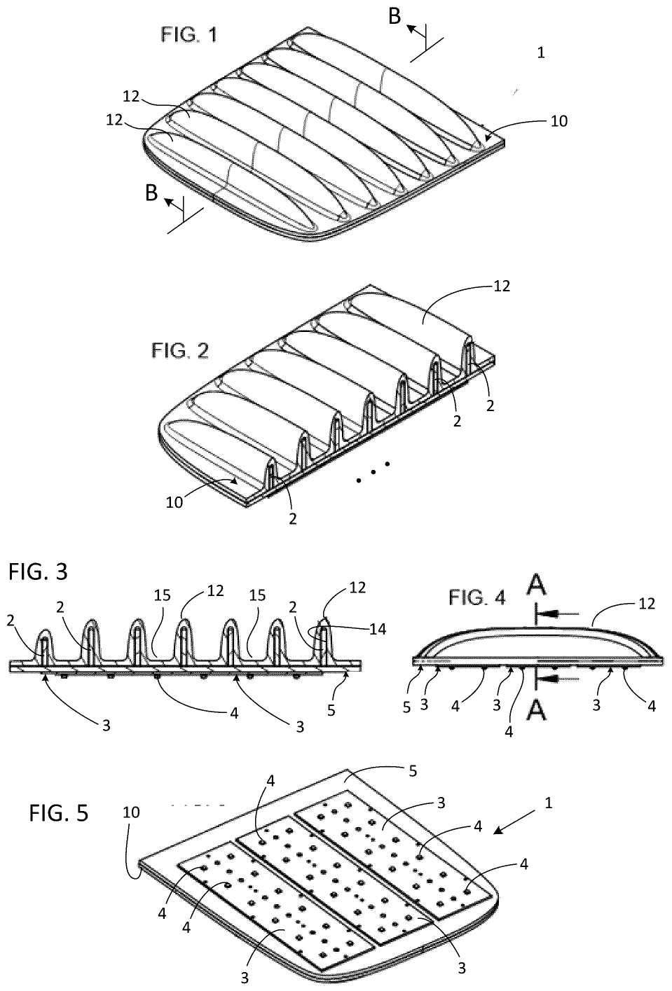

See FIG. 1, which illustrates one embodiment of the heat sink arrangement 1, which comprises an outer covering that forms the fixture housing 10, which has one or, usually, a plurality of laterally spaced apart fins 12 (which may also be termed “ridges”, “bulges”, “protrusions”, etc.) that extend outward, away from the heat-producing members, to increase the surface area through which heat can be dissipated. The fins may, but need not have, the same width, and their respective lengths are chosen to conform to the desired shape of the housing and to the shape of underlying heat-generating parts. In the illustrated embodiment, the ends of the fins taper down to the surface of the housing, which may be done to increase strength or for aesthetic reasons, but is in any case optional and will in general depend on the desired shape and appearance of the housing 10. In the figures, only one or a couple of the fins 12 are labeled with the reference number merely to avoid cluttering the figures. The number of fins 12 provided on the housing may be chosen according to the size and power of the LED lighting fixture as a whole: larger fixtures with more LED elements will in general require more fins for adequate heat dissipation.

See also FIGS. 2 and 3. Openings, grooves or “channels” 14 are formed in the interior of each fin 12 and preferably substantially the whole length of each respective fin, or at least preferably at least over the length of the underlying heat-producing parts of the lighting fixture.

As FIG. 3 best illustrates, within each of the channels 14 is located a relatively highly heat-conductive element 2, which may be in the form of a strip, partial disc, plate, etc., and preferably conforms to the interior shape of the channels. The heat-conductive elements 2 are preferably made of aluminum, copper, or any other chosen metal or combination of metals or other material having a relatively high thermal conductivity. In FIG. 3, the heat-conductive elements 2 are shown as having a rectangular cross-section and extending vertically (viewed as in the figure) more than horizontally, that is, “standing”, and extending substantially perpendicular to the plane of the board 4. This is not a requirement; rather, the elements 2 could extend more “horizontally” (viewed as in FIG. 3), thus “lying”, or could have any other preferred cross-sectional shape, such as square, or triangular or even with an irregular shape, but preferably so as to conform to the cross-section of the interior of the fins so as to maintain good thermal contact between the elements 2 and the interior surface of the channels 14 over the maximum surface area. The housing may be manufactured and assembled easily: the covering can be molded or pressed, and the heat-conducting elements 2 may then be inserted into the channels 14.

The covering/housing 10 and thus the fins 12 are preferably manufactured of a material such as a pressed organic material, minerals, ceramics, sponge, plastics or other synthetics of different types such as hardening plastics or resins, thermoplastic, nylon, PE, PS, PP, ABS (acrylonitrile butadiene styrene), PET (polyethylene terephthalate, that is, “polyester”), PMMA (Poly(methyl methacrylate), PA polyamide (nylon), polycarbonate PC plastic, PVC (polyvinyl chloride), rubber materials, polyurethane, epoxy, composites and synthetic or naturally occurring fibers or natural material such as bio-plastic, or any other covering material that is stiff enough for the particular implementation of the light fixture yet is weather-and preferably even water-resistant so as to protect the interior of the fixture from the elements.

The inventor has found through testing that particularly advantageous materials from which to manufacture the covering/housing 10 and thus the fins 12 are sheet molding compound (SMC), also known as sheet molding composite, which usually refers to both the reinforced composite material and the compression molding process used for it; other thermosetting polymers (sometimes referred to as “thermoset”) and shredded carbon fiber composites also provide the strength and thermal transport properties that are suited to embodiments of the invention, and may similarly be formed by molding, such as compression molding, heat molding, or both.

Note that such materials are even now commonly used to manufacture lighting fixture housings, but prior art heat sink fins are made of such material throughout, that is, solid, or are hollow but without substantially encapsulated heat-conducting elements 2 within interior channels 14. As such, prior art heat sink arrangements for LED lighting fixtures rely solely on the relatively poor heat-conductive properties of the housing material to dissipate heat from the LEDs and their driving circuitry. As mentioned initially, the prior art may attempt to manufacture the housing wholly or partially of aluminum, which provides better heat conduction and dissipation, but this leads to the tendency to corrosion and also usually results in increased weight.

In embodiments of the invention, the plastic, composite, etc., material of the housing 10 also forms a cladding for the heat-conductive elements 2 that substantially encapsulates them, except at the bottom (viewed as in the figures), where the surface of the elements 2 should be as close as possible to and preferably in direct—or as direct as possible—thermal contact with either the intermediate mounting plate/material 5, or the board 3, and thus close to the LEDs 4, with the heat-conducting elements 2 preferably located where heat generation is greatest. Note that the fins 12 need not be evenly spaced.

In the illustrated embodiment, LED light elements 4 (only some of which are numbered, to avoid cluttering the figure) may be mounted on a conventional circuit board 3, with or without built-in heat dissipation plates or surfaces. The board will include conventional conductors and other components to deliver current to the LEDs 4, along with any other desired mechanical or electrical components, for example, drive circuitry, depending on the type of lighting fixture. The board 3 and LEDs together form an LED module that can be installed as such in the fixture during manufacture.

In the figures, an optional mounting and/or spacing layer or plate 5 may be included on the housing 10 to provide a mounting member for the LED module. In a preferred implementation, the covering 10 with inserted heat-conducting elements 2 could be provided together with the plate 5 and could thereby be provided as a pre-assembled unit ready for final manufacturing and assembly. Instead a plate 5, which may be made of, for example, graphite, a thin metallic layer, etc., other thermally conductive materials such as thermal paste may be used. The plate 5, or whatever other configuration is used to function as the plate, if included at all, may be attached to the bottom surface of the covering using any known material and method suitable to the respective materials the parts are made of. The means of attachment should preferably not, however, significantly impede heat flow from the board 4 into the heat-conducting elements 2. In any case, the covering 10 will generally be provided on the opposite side of the board 3 from the LEDs.

When the LEDs 4 are energized they will shine downward (if oriented as in the figures), typically through some translucent covering (not shown) of glass or suitable plastic. Heat will then flow from the LEDs and board 4, through the optional mounting plate (if included) and into the heat-conductive elements 2. From there it will flow though the fins 12 of the covering 10, as well as partially through the “valleys” 15 between the fins 13.

As FIG. 5 illustrates, more than one LED module 3, 4 may be included in a single fixture 1.

The heat-conducting elements 2 have both higher heat capacity and higher thermal conductivity than the covering, which is preferably not made of metal, but rather of a material with a relatively lower—even much lower—thermal conductivity than the elements 2. If the walls of the fins 12 were as thick as prior art heat sink fins, heat would be similarly trapped, even though the elements 2 would be able to hold more heat than, for example, plastic or ceramic, thereby delaying a temperature increase at the board 3. Note that the mounting plate 5 itself, if included, may also conduct and dissipate some heat as well, depending on what material it is made of.

In the preferred embodiments, however, the fins may be made thinner than in the prior art. In one prototype, for example, the heat-conducting elements 2 were 3 mm wide, and the fins were at most 2 mm thick at the thinnest part, namely, the fin wall adjacent to the vertical (as viewed in FIG. 3) surfaces of the heat-conducting elements 2, increasing to at most 10 mm at the base. This decreased thickness relative to prior art fin arrangements proved in tests to prevent standard LED diodes from overheating and to maintain a suitable operating temperature. Note that fin thickness will in general be more a matter of durability than of heat transport: the inserted heat-conducting elements 2 will themselves provide rigidity.

1. An LED lighting fixture comprising:
a plurality of LEDs mounted on a board, together forming an LED module;
a covering provided on the LED module on an opposite side of the board relative to the LEDs, said covering having at least one fin extending substantially perpendicular to the LED module;
said at least one fin having an internal channel;
a heat-conducting element having greater thermal conductivity than the fin and being provided within the channel, the heat-conducting element thereby being substantially encapsulated by the fin.

2. The LED lighting fixture according to claim 1, in which the covering is made of a material chosen from the group including pressed organic material, minerals, ceramics, sponge, plastics or other synthetics of different types such as hardening plastics or resins, sheet molding compound, thermoplastic, nylon, PE, PS, and PP plastic, ABS, PET, PMMA, polyamide PA, polycarbonate PC, PVC, rubber materials, polyurethane, epoxy, composites, synthetic and naturally occurring fibers, and bio-plastic.

3. The LED lighting fixture according to claim 2, in which each heat-conducting element is manufactured from a metal.

4. The LED lighting fixture according to claim 3, in which each heat-conducting element is manufactured from at least one of the group including aluminum and copper.

5. The LED lighting fixture according to claim 1, further comprising a mounting member located between the LED module and the covering.

6. The LED lighting fixture according to claim 5, in which the mounting member is a plate.

7. The LED lighting fixture according to claim 5, in which the mounting member is a layer of thermal paste.

8. The LED lighting fixture according to claim 3, in which the fin has a maximum thickness of 2 mm laterally adjacent to its respective encapsulated heat-conducting element.

9. An LED lighting fixture comprising:
a plurality of LEDs mounted on a board, together forming an LED module;
a covering provided on the LED module on an opposite side of the board relative to the LEDs, said covering having at least one fin extending substantially perpendicular to the LED module;
said at least one fin having an internal channel;
a heat-conducting element having greater thermal conductivity than the fin and being provided within the channel, the heat-conducting element thereby being substantially encapsulated by the fin;
a mounting member located between the LED module and the covering;
in which:
the covering is made of a material chosen from the group including pressed organic material, minerals, ceramics, sponge, plastics or other synthetics of different types such as hardening plastics or resins, sheet molding compound, thermoplastic, nylon, PE, PS, and PP plastic, ABS, PET, PMMA, polyamide PA, polycarbonate PC, PVC, rubber materials, polyurethane, epoxy, composites, synthetic and naturally occurring fibers, and bio-plastic; and
each heat-conducting element is manufactured from a metal manufactured from at least one of the group including aluminum and copper.

10. The LED lighting fixture according to claim 9, in which the fin has a maximum thickness of 2 mm laterally adjacent to its respective encapsulated heat-conducting element.
